(19) United States
(12) Patent Application Publication
(10) Pub. No.: US 2008/0026143 A1
(43) Pub. Date: Jan. 31, 2008

(54) Process for flourinating piping

(76) Inventor: Michael Clark Webb, Raleigh, NC (US)

Correspondence Address: Michael C. Webb;c/o Environ Products, 3250 US Hgwy 70 Business West, Smithfield, NC, 27577, US

(21) Appl. No.: 11/491,860

(22) Filed: Jul. 25, 2006

(51) Int. Cl. B05D 7/22; C23C 14/00; C23C 16/00

(52) U.S. Cl. 427/237; 427/255.26

(57) ABSTRACT

A method of fluorinating the wall surfaces of single wall and double wall polyethylene pipe after it has been extruded and coiled onto a roll or reel. A fluorination apparatus cooperative with a continuous coiled pipe is set forth. In the preferred and illustrated embodiment, a continuous coiled pipe is in sealed communication with a fluorination apparatus that enables a gaseous impregnation of the pipes surfaces with gas exposure including fluorine. When exposed to the fluorine gas the pipes surface is changed creating an improved permeation barrier for fuels and other hazardous fluids. After exposure to the fluorine, the unreacted fluorine is evacuated from the pipe. This procedure can be optionally repeated to increase the levels of fluorination.

### CITED REFERENCES

CITED REFERENCES

| | | |
|---|---|---|
| 6,565,127 | Mar. 7, 2002 | Webb |
| 5,911,155 | Jun. 8, 1999 | Webb |
| 5,792,528 | Aug. 11, 1998 | Carstens |
| 5,770,135 | Jun. 23, 1998 | Hobbs |
| 5,527,130 | Jun. 18, 1996 | Webb |
| 5,401,451 | Mar. 28, 1995 | Meixner |
| 4,869,559 | Sep. 26, 1989 | Eschwey |
| 4,743,419 | May 10, 1998 | Bierschenk |
| 4,536,266 | Aug. 20, 1985 | Bliefert |
| 4,296,151 | Oct. 20, 1981 | Boultinghouse |
| 4,142,032 | Feb. 27, 1979 | D'Angelo |
| 3,862,284 | Jan. 21, 1975 | Dixon |

### BACKGROUND OF THE INVENTION

In recent years there has been an increased awareness that the underground storage and distribution systems of hazardous fluids, such as, hydrocarbon fuels and a diversity of chemicals, need to be improved to prevent any leaking product from these systems from escaping into the environment and potentially contaminating the underground drinking water. Both public health and fire safety regulatory bodies have imposed strict guidelines and regulations on such systems to insure public safety.

Leaking underground storage tanks and their associated underground piping systems became the focus of the Federal Environmental Protection Agency (EPA) to initiate federal and state legislation that would require an improved means of storage, distribution, leak detection and accounting of all stored fluids which are deemed to be hazardous. The EPA conducted studies that showed that underground piping failures were caused by poor installation practices; corrosion and structural failure were responsible for most of the leaks reported.

In response to this public awareness and concern, equipment specifiers and manufacturers have developed improved piping systems in recent years to provide a greater degree of protection for the environment. Most of these improved piping systems provide a second barrier of protection around the primary fluid supply piping, commonly referred to as “secondary containment”.

In addition to the regulatory bodies mentioned above, facility owners, fuel retailers and their insurance companies have become very concerned with the type of materials used and the design specifications of existing, new and proposed fuel storage, transmission and dispensing equipment.

An important area of concern is the chemical compatibility of the materials used in the construction of both the primary and secondary piping systems. As a result, Underwriters Laboratories Inc. (UL), a nationally recognized and accepted independent testing laboratory, has already established and proposed new standards for the primary and secondary piping for underground fuel piping systems. Acceptable materials for use in this application generally relate to the materials stability when exposed to conditions and chemicals found naturally in a subterranean environment and the exposure to the fuels and their chemical additives, as well as other chemicals being stored and dispensed.

In addition, another area of concern is ability of a material to provide an acceptable containment barrier for the product to be stored. It is generally accepted by environmental regulators and UL that the fuel permeation rating for primary carrier pipe be lower than for the secondary containment pipe, that only provides a means of temporary storage of leaking product until detected and corrected.

For example, UL has established and proposed new standards that include acceptable permeability levels for the primary containment and secondary containment storage and dispensing systems. These standards require that primary carrier pipe shall have a maximum allowable permeation value of 1.0 g/m² per day and the secondary containment pipe shall have a maximum allowable permeation value of 4.0 g/m² per day. Keeping these standards in mind, UL listed products for storage of hazardous liquids and fuels must be constructed of the proper materials at the acceptable thickness to provide a satisfactory level of environmental protection and fire safety.

For purpose of this description, “underground piping systems” is defined as the means of transferring hazardous liquids or gases, such as gasoline and gasoline vapors underground. These piping systems are typically found at service stations that dispense gasoline and diesel fuels. One type of underground fuel piping is referred to as “supply pipe” that transfers liquid fuel from an underground storage tank, by the tank's electrically powered “dispensing pump” to an above ground metered dispensing unit or dispencer. Another type of underground pipe is a “vent pipe” that connects the tank to a vertical vent stack for purposes of venting the tank. Yet another type of underground pipe is a “vapor return pipe” that transfers fuel vapor and condensed liquid fuel from the dispenser back to the tank. Most of the previously described pipe typically range inside diameter from 1½″ to 3″. Some services stations use “remote fill pipe” that is even larger diameter (4″ ID) that connects a remotely located fill box to a tank for delivering fuel to the tank. An underground piping system that is secondarily contained by a larger diameter piping system is generally referred to as a “double-wall piping system”.

Equipment manufacturers have in recent years introduced both patented and non-patented supply piping systems and/or secondary containment systems for these piping systems of various designs and material selections. The introduction of continuous flexible supply pipe, in recent years, was a means of reducing the amount of connection joints in the supply pipe compared to the commonly used non-flexible piping systems like steel and fiberglass pipe systems. Some notable advantages of these flexible piping systems versus non-flexible piping systems, include considerably fewer piping joints, they may be replaceable without the need for excavation and they are available on rolls or reels in long continuous lengths. From these long lengths, pipe sections may be custom cut to length for installation between two or more surface access sumps. This feature eliminates the need for any directional fittings in the pipeline, thus eliminating the need of any piping joints between the interconnected access sumps. The flexible supply piping does require the use of directional fittings but these fittings are located within the surface access sumps where they are surface accessible for inspection and maintenance. This piping design permits complete access to and observation of all the primary and secondary piping joints from the ground surface without the need for excavation.

Flexible underground piping is available in both a single wall and double wall constructions. The single wall flexible pipe construction can be extruded with one or more thermoplastic layers. At least one layer is made of a high performance plastic, like nylon or a fluoropolymer, to restrict fuel permeation through the wall of the pipe. Other layer(s) are typically made of lower cost plastics that are reasonably compatible with fuels but insufficient to restrict fuel permeation to acceptable levels. In some flexible piping constructions a tie layer or adhesive is necessary to bond the permeation barrier layer to other layers made of dissimilar materials.

A double wall flexible pipe construction usually has the single wall construction, as described above, as the inner primary pipe and either a single of multi-layer extruded pipe as the secondary pipe. The fuel permeation and performance requirements for the secondary pipe are usually much less stringent than for the primary pipe.

One such double wall flexible construction which has proven over time to be very popular and effective is described in U.S. Pat. Nos. 5,297,896, 5,527,130, 5,927,762, 6,565,127. These patents describe a double wall coaxial, flexible underground piping system and their associated double wall couplings and fittings.

Specifically theses patents describe a double wall pipe including an inner pipe, and an outer pipe which is in radial communication with the outside surface of the inner pipe in such a manner that a small interstitial space between both walls is created to permit fluid and gas migration from one end of a pipe section to the other end. This flexible double wall pipe includes a plurality of internally facing longitudinal ribs on the inner surface of the outer pipe, or externally facing longitudinal ribs on the outer surface of the inner pipe. In either design, a plurality of circumferentially spaced ribs extend radially from one of the pipe members to the other pipe member such that the ribs have a surface which confronts and snugly engages the other pipe to define the interstitial space between the two pipes. The confronting surfaces of the ribs have a predetermined configuration in at least the longitudinal direction to permit migration of fluid in the interstitial spaces in all directions.

The flexible double wall piping described in these patents also describe a double wall pipe coupling and fitting system that permits the interstitial space of pipeline, made up of two or more pipes sections, to transition from one pipe section to the next.

A flexible double wall pipe, as described above, that has an inner primary pipe with an integral outer secondary pipe that are rolled up, shipped and installed together as one has become the most widely accepted double wall underground piping system. Some of these flexible double wall piping constructions may have as many a nine bonded and/or un-bonded layers. Too many pipe layers can become complicated and very expensive to extrude. Too many un-bonded layers can cause problems when installing fittings due to misalignment of pipe layers.

On method of creating an effective fuel permeation barrier without incorporation of a high performance thermoplastic materials, such as a nylon or fluoropolymers, is a process called surface fluorination. Fluorination of plastic for enhanced fuel barrier properties has been known since the mid 1950's when patents were first issued. Many of the vehicle fuel tanks that are being produced today are made of a blow molded thermoplastic material, such as high density polyethylene (HDPE). Untreated polyethylene for the production of fuel tanks, has the disadvantage of being relatively permeable to fuel leading to leakage as much as 20 g per day from an average fuel tank. The automobile industry today accepts a leakage of around 2 g per day, but is striving to attain a maximum level of 0.2 g per day as the standard for the future. Such a figure is achievable through the addition of fuel barrier layers such as, nylons and fluoropolymers or by a surface treatment process to the polyethylene called direct fluorination. The permeation of fuel through polyethylene fuel-container walls can be dramatically reduced by the chemical process of forming a fluorination layer on the inside surface of the tank.

Fluorine is chemically bonded to the chain-like molecules on the outermost surfaces of the plastic. The reaction is permanent and forms a thin fluorocarbon polymer surface layer with heightened chemical stability. Once grafted in place, the fluorine is permanent and not readily removable, nor does it become unbound with time.

This barrier greatly reduces the permeation of fuels and the softening and/or swelling of the material treated. This allows inexpensive thermoplastics such as, polyethylene to be used in fuel tank and piping applications with aggressive fuels where an untreated tanks and piping would have marginal success in containing the product.

There are two common methods of surface fluorination of polyethylene tanks and piping. The first method is a post molded process, whereby the molded tanks or extruded pipe sections are placed into a sealed reactor and exposed to a measured amount of elemental fluorine gas under specifically controlled conditions whereby various levels of surface fluorination can be achieved, depending upon the application requirements. The second method is an in-process method common with blow molding of automobile fuel tanks and plastic jerry cans. In this application the fluorine gas is injected into the blow molded part while it is starting to cool down and before the part is released. Both of these fluorination methods produce permanent molecular bonding on the exposed surfaces of the polyolefin substrate.

Surface fluorination of a polyolefin, such as, high density polyethylene, is an effective means of creating a thermoplastic pipe that is compatible with virtually all fuel types and has extremely low fuel permeation rates. Fluorinated polyethylene pipe is typically less expensive to produce than multilayer pipe construction that usually incorporates expensive barrier resins.

### SUMMARY OF THE INVENTION

It is the objective of the present invention to provide an improved process for surface fluorinating of flexible piping that is plastic extruded and coiled into rolls or onto reels. This process would produce an environmentally safe single wall and double wall piping systems that improves on previous underground piping designs at lower in cost to produce. These fluorinated, double wall piping systems are intended to be used for conveying hazardous liquids, such as gasoline, from an underground storage tank to an above ground dispensing unit typically found at fuel service stations.

Specifically, a method of fluorinating one or more surfaces of single wall or double wall pipe after the pipe has been extruded and coiled into a roll or onto a reel. A roll or reel of flexible underground fuel piping could be as long as five thousand feet (5,000′) in length. The two common methods of surface fluorination of fuel tanks, jerry cans and short lengths of fuel pipe (20 feet or less) can not produce an even of effective fluorinated surface barrier on the inside wall(s) for long lengths of coiled flexible pipe.

It is for this reason, that the object of this invention is to create new method of surface fluorination that produces an even and effective fuel barrier on the inside surfaces of a single wall and double wall flexible pipe after it has been extruded and coiled into rolls or onto reels.

Thermoplastic flexible fuel piping is typically heat and pressure extruded of one or more layers and then cooled down before being coiled onto a take-up reel. Single wall pipe may have one layer or could have a number of bonded or un-bonded layers. Double wall or “coaxial” pipe would have an inner primary pipe, like previously described, but also an un-bonded secondary containment pipe with small stand-off legs or ribs to create a small interstitial space between the outside surface of the primary pipe and the inside surface of the secondary containment pipe. The secondary pipe for this type of flexible double wall pipe is integral with the inner primary pipe meaning they are extruded together, coiled together, shipped together and installed together.

This new method of surface fluorination for coiled flexible piping relates to process whereby the following exposed pipe surfaces could be treated: a) the inside surface of the primary pipe; b) the outside surface of the primary pipe; and c) the inside surface of the secondary pipe.

This process would include one or more rolls or reels of coiled flexible piping or pipe reels placed into an isolation chamber that is designed protects workers from being exposed to the fluorinating agent or gas during and after the treatment process. Each end of the coiled pipe would be fitted with either a single wall pipe coupling or double wall pipe coupling. At one coupled pipe end of the pipe reel, the coupling would be connected to an inlet connector that passes through the wall of the isolation chamber and connects to the fluorinating equipment. The other coupled end of the pipe reel would be connected to either coupled end of another pipe reel or to an outlet connector that passes through the wall of the isolation chamber and connects to the fluorinating system. Two or more pipe reels may be connected together in series or “daisy chained” and one pipe reel connected to the inlet connector and another connected to the outlet connector.

Once one or more pipe reels are interconnected to the inlet connector and outlet connector and the doors to the isolation chamber are sealed and the process of fluorination may begin. The fluorinating equipment is a complex system including fluorinating gasses, controls, control valves, vacuum pumps, pressure pumps, heaters, environmental scrubbers and other equipment. Heat is introduced to the coiled pipe either internally or externally to raise the temperature of the pipe to a temperature between 122° to 140° F. (50° to 60° C.). A vacuum between −10 and −15 Hg in.) is then applied to the inside of the primary pipe and the interstice of a double wall pipe to evacuate the oxygen contained inside. After a vacuum has been applied, the fluorinating agent or gas is introduced into the inside of the primary pipe and the interstice of a double wall pipe. Once the pressure has equalized, a low positive pressure of fluorinating agent, a gas mixture, is applied to insure that all surface areas within the primary pipe and interstice are adequately exposed and treated. After a period of 20 to 30 minutes of exposure the process may be repeated again to achieve the desired level of fluorination.

After the fluorination exposure period is over, the spent fluorinating agent is evacuated from the inside of the piping and interstice into an environmental scrubber tank that neutralizes the spent fluorinating agent in to a harmless gas that can be vented into the atmosphere. A suitable scrubber tank would be a vertical wet scrubber having a mixture of 40% potassium hydroxide and 60% water. After all of the safety precautions have been met, the doors to the isolation chamber can be opened and the pipe reels disconnected and removed.

### BRIEF DESCRIPTION OF THE DRAWINGS

FIG. 1 is a diagrammatic plan view of a flexible underground piping system connecting underground storage tanks to fuel dispensers.

FIG. 2 is a side view of a flexible underground piping system connecting an underground storage tank to two fuel dispensers.

FIG. 3 is an end view of a single wall flexible underground fuel pipe.

FIG. 4 is an end view of a double wall or coaxial flexible underground fuel pipe.

FIG. 5 is a side view of a pipe reel.

FIG. 6 is a side view of the coupled end of a double wall pipe connected to a hose connector and tube connector.

FIG. 7 is a side cutaway view of the isolation chamber containing pipe reels.

FIG. 8 is a front view of the fluorination system and the isolation chamber containing a pipe reel.

### DESCRIPTION OF THE INVENTION

The present invention derives from the recognition that there needs to be an effective method of fluorinating the inside surfaces of a single and double wall flexible pipe that is shipped in long continuous lengths on a roll or reel. Fluorination flexible polyethylene piping improves its fuel compatibility, reduces fuel permeation and lowers the cost compared to multi layered fuel pipe.

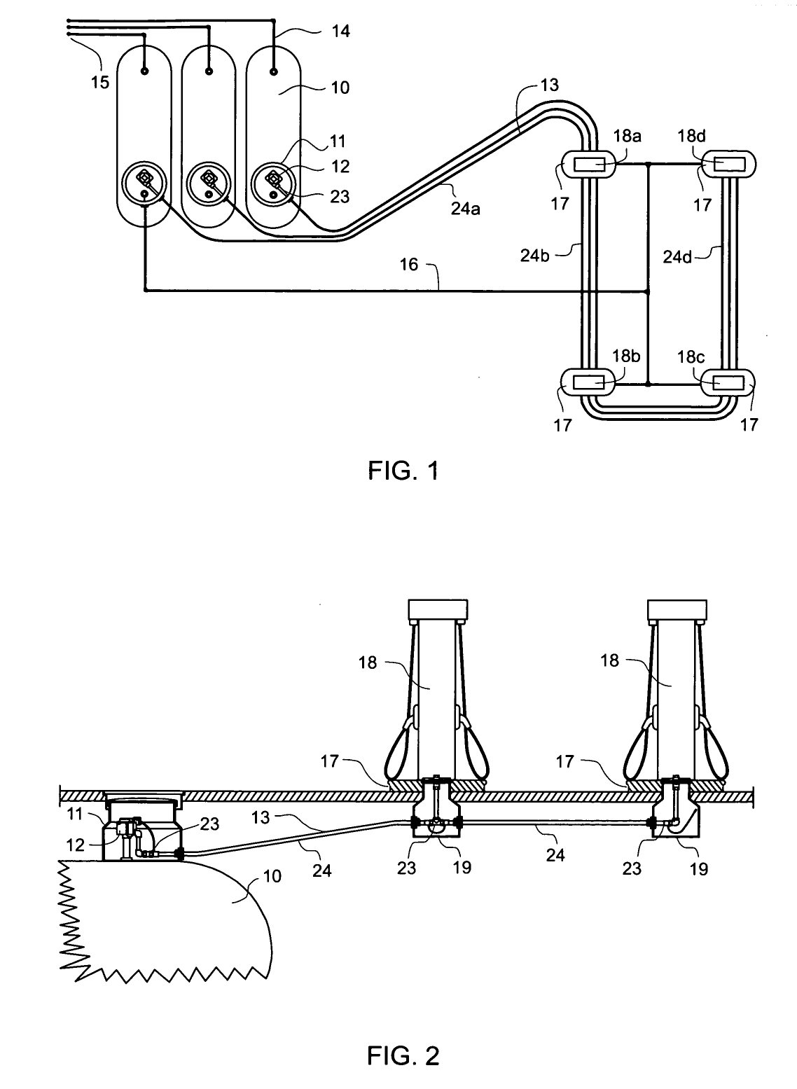

Turning first to FIG. 1 and FIG. 2 of the attached drawings, therein illustrated is fuel storage, piping and dispensing system typically installed at a retail service station. There is at least one underground storage tank 10 connected to a vent stack 15 by vent pipeline 14 for venting said tank 10. A pump 12 and pipe connections 23 are contained inside of a tank sump 11, located on top of the tank 10. The pump 12 is connected to a number of dispensers 18 by a supply pipeline 13, containing one or more pipe sections 24. The first pipe section 24a connects the pump 12 to the first dispenser 18a, installed on a concrete island 17. The first dispenser 18a is connected to the next dispenser 18b by the second pipe section 24b and so on until the supply pipeline 13 is terminated in the last dispenser 18d. Under each dispenser 18 is a dispenser sump 19 for containment of the pipe connections 23.

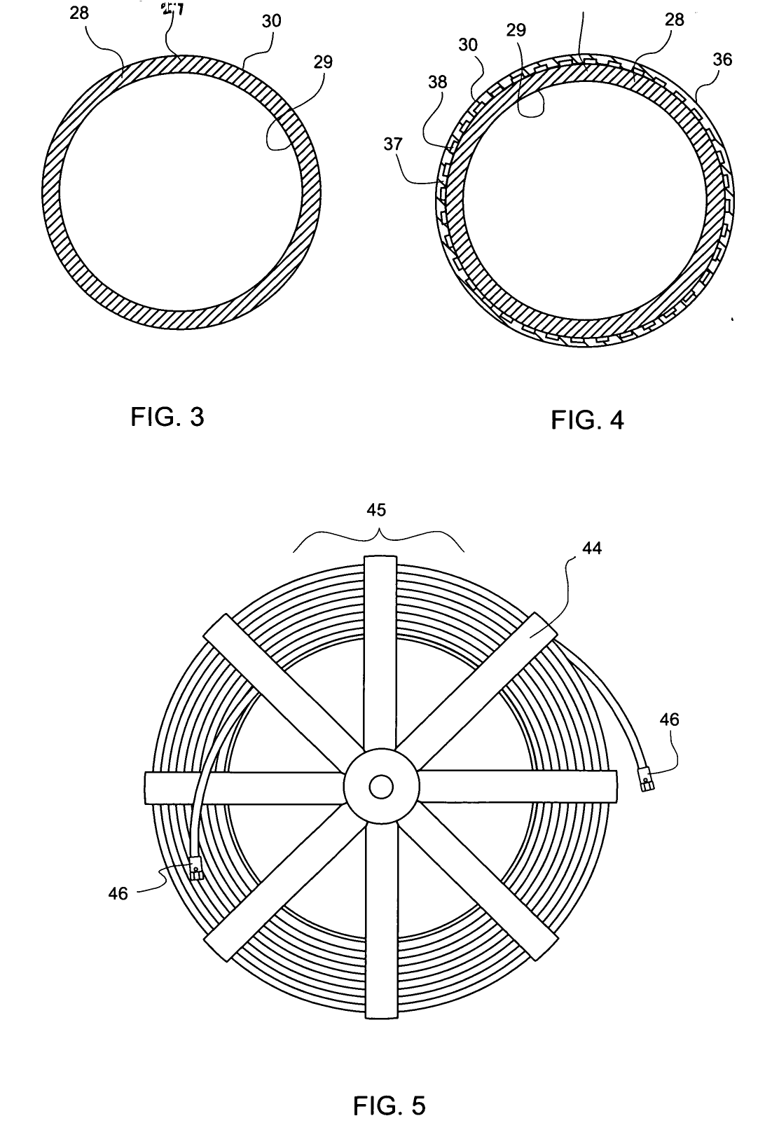

As illustrated in FIG. 3, a single wall pipe 27 that contains fuel, has an inside surface 29 that is exposed to the fuel at all times. Typically it is this inside surface 29 of the primary pipe 28 that has fuel permeation barrier. The permeation barrier could be a fluorinated surface treatment or be a thermoplastic barrier layer made of a fluoropolymer or nylon material. The primary pipe 28 has an outside surface 30 that is not always required to have a fuel permeation barrier applied.

FIG. 4, illustrates a double wall pipe 27 or coaxial pipe that has an inner primary pipe 28 contained within an outer secondary pipe 36. The primary pipe 28 would similar to the pipe described in FIG. 3, with the exception that it would typically be required to have a fuel permeation barrier applied to its outside surface 30. The secondary pipe 36 or jacket shown, has a multitude of stand-off legs 37 on its inside surface 29 that create an interstitial space or interstice 38 between the outside surface 30 of the primary pipe 28 and the inside surface 29 of the secondary pipe 36. The inside surface 29 of the secondary pipe 36 should have a fuel permeation barrier applied such as, a fluorinated surface treatment or a thermoplastic barrier layer made of a fluoropolymer or nylon material. The outside surface of the secondary pipe is not always required to have a fuel permeation barrier applied.

FIG. 5 shows a flexible pipe 25 coiled onto a reel 44 that makes up a pipe reel 45. Each coupled end 46 of the flexible pipe 25 are made easily accessible for integrity testing and for fluorination.

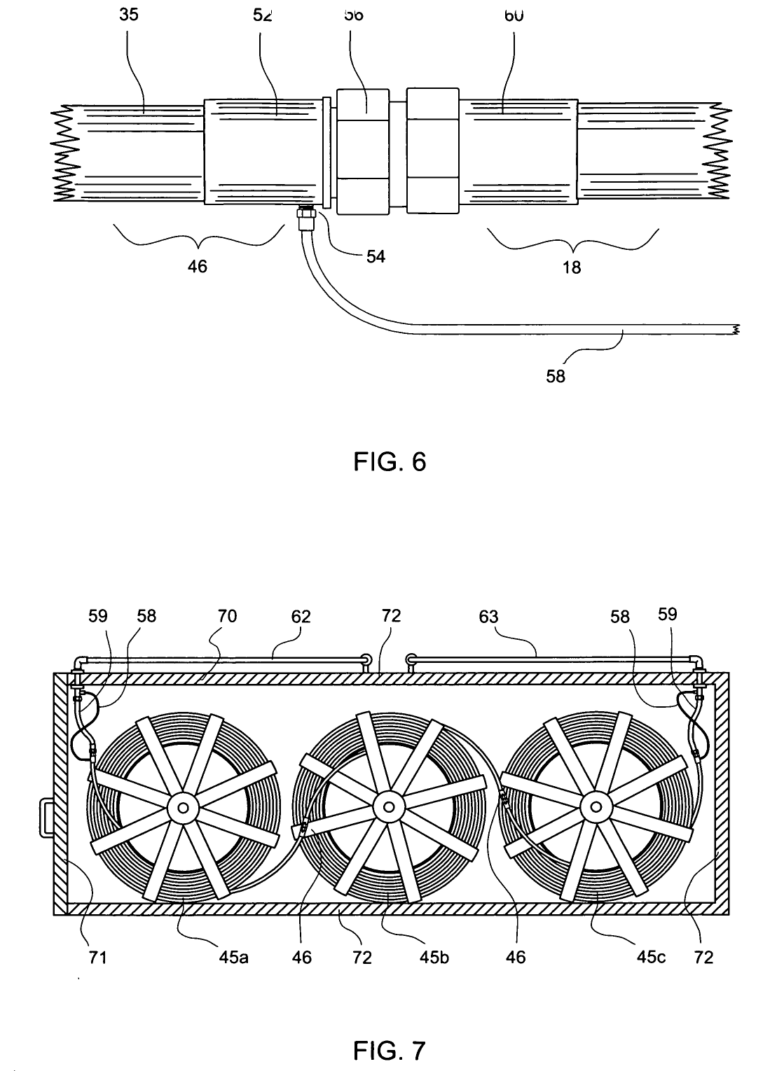

Illustrated in FIG. 6 is a coupled end 46 of a flexible pipe 26 connected to a connector hose 18 and a connector tube 58. The coupled end 46 has a double wall coupling 52 having a swivel nut 56 for connection to the connector coupling 60. The double wall coupling 52 has an interstitial access port 54 for connection of the connector tube 58.

Shown in FIG. 7 is a cutaway view of the isolation chamber 70 containing three pipe reels 45. A typical isolation chamber 70 would have five chamber walls 72 and one chamber door 71 for interior access. The coupled end 46 of the front pipe reel 45a is connected to a connector hose 59 and connector tube 58 that are connected to the supply line 62 on their other end. The center pipe reel 45b is connected together on its coupled ends 46 to the front pipe reel 45a and to the back pipe reel 45c in series method or “daisy chained”. The other coupled end 46 of the front pipe reel 45c is connected to a connector hose 59 and connector tube 58 that are connected to the return line 63 on their other end.

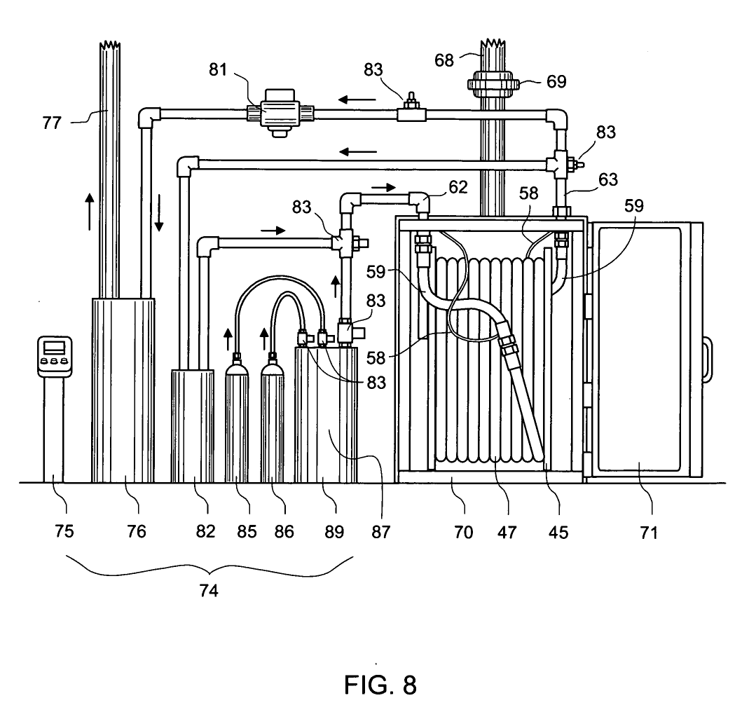

FIG. 8 shows the fluorination system 74 connected to the isolation chamber 70 by means of the supply line 62 and a return line 63. By keeping the chamber door 71, of the isolation chamber 70, closed during the fluorination process, workers can be protected from any leaking gas that could be harmful. At the end of the fluorination process a vent fan 69 is activated to evacuate any leaking gas out through the chamber vent 68, as a safety precaution. The supply line 62 and return line 63 are connected to a hot air blower 82 to circulate hot air though the inside of the primary pipe 28 to warm up all of the coiled pipe 47 to a desired temperature. A series of control valves 83 regulated by the controller 75 allows hot air to be supplied from the hot air blower 82 to the coiled pipe 47 through the supply line 62 and returned back through the return line 63.

The return line 63 is connected to a vacuum pump 81 to draw a vacuum on the inside of the primary pipe 28 and also the interstice 38 of a double wall pipe. The applied vacuum evacuates the oxygen contained inside. A series of control valves 83 regulated by the controller 75 allows the vacuum pump 81 to draw a vacuum on the coiled pipe 47.

The supply line 62 is connected to a reactor tank 89 where the fluorine gas 85 with bromine gas 86 are mixed to create fluorinating agent 87. A series of control valves 83 regulated by the controller 75 regulates the gas mixture in the reactor tank 89 and the supply of fluorinating agent 87 through the supply line 62 to the coiled pipe 47.

After the fluorinating agent 87 has been pumped into the coiled pipe 47 and after a certain period of time the spent fluorinating agent 87 is vacuumed out of the coiled pipe 47 though the return line 63. A series of control valves 83 regulated by the controller 75 allows the vacuum pump 81 to vacuum out the spent fluorinating agent 87 contained in the coiled pipe 47 and transfer it though the return line 63 to a scrubber tank 76 that contains a chemical mixture that neutralizes the spent fluorinating agent 87 and makes it safe to be vented out through the scrubber vent 77 into the atmosphere.

What is claimed is:

1. A method of fluorination of a single wall polyethylene pipe having a smooth inside surface in contact with fluid and an outside surface, comprising the steps of:
(a) extruding a continuous length of said pipe and coiling into a roll or onto a reel;
(b) making a sealed connection between the inside of said pipe and a vessel containing a: fluorine fixture made of a fluorine gas mixed with an inert gas;
(c) introducing and exposing the fluorine mixture to the inside surface of said pipe for a prescribes period of time;
(d) evacuating the surplus fluorine mixture from the inside of said pipe; and
(e) wherein the step of introducing and exposing the inside of said pipe to a fluorine mixture occurs in an isolated atmosphere subject to the evacuation of surplus fluorine or compounds from the isolated atmosphere.

2. The method of claim 1 wherein the inside of said pipe is a flexible underground pipe use for the containment and transmission of fuels and other hazardous liquids.

3. The method of claim 1 wherein the steps of introducing and exposing the inside surface of said pipe to a fluorine mixture within an isolated atmosphere and then evacuating the surplus fluorine or compounds from the isolated atmosphere can be repeated to achieve higher levels of surface fluorination.

4. The method of claim 1 where a vacuum is applied to the inside of said pipe to remove oxygen, prior to introducing and exposing the fluorine mixture to the inside of said pipe.

5. The method of claim 1 a means of heating said pipe to a desired temperature prior to introducing and exposing the fluorine mixture to the inside of said pipe.

6. The method of claim, 1 where the fluorine gas is diluted with nitrogen.

7. The method of claim 1, wherein the fluorine cross-links with polyethylene polymers to modify the inside surface of the pipe.

8. A method of fluorination of a double wall polyethylene pipe, having an inner pipe with a smooth inside surface in contact with fluid and an outside surface in communication with stand-offs defining an interstitial space between the outside surface of the inner pipe and the inside surface of the outer pipe, comprising the steps of:
(a) extruding a continuous length of said pipe and coiling into a roll or onto a reel;
(b) making a sealed connection between the inside of the said inner pipe and said interstitial space with a vessel containing a fluorine mixture made of a fluorine gas mixed with an inert gas;
(c) introducing and exposing the fluorine mixture to the inside of said inner pipe and said interstitial space for a prescribed period of time;
(d) evacuating the surplus fluorine mixture from the inside of said inner pipe and said interstitial space; and
(e) wherein the step of introducing and exposing the inside of said inner pipe and said interstitial space to a fluorine mixture occurs in an isolated atmosphere subject to the evacuation of surplus fluorine or compounds from the isolated atmosphere.

9. The method of claim 8 wherein the inside of said pipe is a flexible underground pipe use for the containment and transmission of fuels and other hazardous liquids.

10. The method of claim 8 wherein the steps of introducing and exposing the inside of said pipe to a fluorine mixture within an isolated atmosphere and then evacuating the surplus fluorine or compounds from the isolated atmosphere can be repeated to achieve higher levels of surface fluorination.

11. The method of claim 8 where a vacuum is applied to the inside of said inner pipe and said interstitial space to remove oxygen, prior to introducing and exposing the fluorine mixture to the inside of said pipe.

12. The method of claim 8 a means of heating said pipe to a desired temperature prior to introducing and exposing the fluorine mixture to the inside of side pipe.

13. The method of claim, 8 where the fluorine gas is diluted with nitrogen.

14. The method of claim 8, wherein the fluorine cross-links with polyethylene polymers to modify the inside surface and outside surface of said inner pipe and inside surface of the outer pipe.
